(19) United States
(12) Patent Application Publication
(10) Pub. No.: US 2023/0086984 A1
(43) Pub. Date: Mar. 23, 2023

(54) BEAM ARRAY GEOMETRY OPTIMIZER FOR MULTI-BEAM INSPECTION SYSTEM

(71) Applicant: ASML Netherlands B.V., Veldhoven (NL)

(72) Inventors: Te-Yu CHEN, San Jose, CA (US); Martinus Gerardus Johannes Maria MAASSEN, San Francisco, CA (US)

(73) Assignee: ASML Netherlands B.V., Veldhoven (NL)

(21) Appl. No.: 17/909,352

(22) PCT Filed: Feb. 24, 2021
(86) PCT No.: PCT/EP2021/054608

§ 371 Date: Sep. 2, 2022

Related U.S. Application Data
(60) Provisional application No. 62/985,669, filed on Mar. 5, 2020.

(51) Int. Cl. H01J 37/28; H01J 37/29

(52) U.S. Cl. CPC H01J 37/28; H01J 37/292; H01J 2237/0435; H01J 2237/1205; H01J 2237/24592; H01J 2237/2817

(57) ABSTRACT

Apparatuses, systems, and methods for beam array geometry optimization of a multi-beam inspection tool are disclosed. In some embodiments, a microelectromechanical system (MEMS) may include a first row of apertures; a second row of apertures positioned below the first row of apertures; a third row of apertures positioned below the second row of apertures; and a fourth row of apertures positioned below the third row of apertures; wherein the first, second, third, and fourth rows are parallel to each other in a first direction; the first and third rows are offset from the second and fourth rows in a second direction that is perpendicular to the first direction; the first and third rows have a first length; the second and fourth rows have a second length; and the first length is longer than the second length in the second direction.

### CROSS-REFERENCE TO RELATED APPLICATIONS

This application claims priority of U.S. application 62/985,669 which was filed on Mar. 5, 2020, and which is incorporated herein in its entirety by reference.

### TECHNICAL FIELD

The description herein relates to the field of charged particle beam systems, and more particularly to beam array geometry optimization for multi-beam inspection systems.

### BACKGROUND

In manufacturing processes of integrated circuits (ICs), unfinished or finished circuit components are inspected to ensure that they are manufactured according to design and are free of defects. Inspection systems utilizing optical microscopes or charged particle (e.g., electron) beam microscopes, such as a scanning electron microscope (SEM) can be employed. SEM delivers low (e.g., <1 keV) or high energy electrons to a surface and records secondary or backscattered electrons leaving the surface using a detector. By recording such electrons for different excitation positions on the surface, an image can be created with a spatial resolution in the order of nanometers.

The SEM may be a single-beam system or a multi-beam system. A single-beam SEM uses a single electron beam to scan the surface, while a multi-beam SEM uses multiple electron beams to scan the surface simultaneously. The multi-beam system may achieve a higher throughput of imaging compared with the single-beam system. However, the multi-beam system also has more complicated structures, due to which it lacks some structural flexibility. Optimizing throughput of imaging in a multi-beam system can be difficult due to its higher complexity.

### SUMMARY

Embodiments of the present disclosure provide apparatuses, systems, and methods for beam array geometry optimization of a multi-beam inspection tool. In some embodiments, a microelectromechanical system (MEMS) may include a first row of apertures; a second row of apertures; a third row of apertures; and a fourth row of apertures; wherein the first, second, third, and fourth rows are parallel to each other in a first direction; the first and third rows are offset from the second and fourth rows in a second direction that is perpendicular to the first direction; the first and third rows have a first length; the second and fourth rows have a second length; and the first length is longer than the second length in the second direction.

In some embodiments, a MEMS structure may include a first structure, comprising a first row of apertures; a second row of apertures positioned below the first row of apertures; a third row of apertures positioned below the second row of apertures; a fourth row of apertures positioned below the third row of apertures; wherein the first, second, third, and fourth rows are parallel to each other in a first direction; the first and third rows are offset from the second and fourth rows in a second direction that is perpendicular to the first direction; the first and third rows have a first length; the second and fourth rows have a second length; and the first length is longer than the second length in the second direction; a second structure comprising an array of apertures forming a hexagonal shape; and wherein the first structure is superimposed on the second structure.

In some embodiments, a charged particle multi-beam system for generating a plurality of beams for inspecting a wafer positioned on a stage may include a first structure and a second structure. The first structure may include a first row of apertures; a second row of apertures; a third row of apertures; a fourth row of apertures; wherein the first, second, third, and fourth rows are parallel to each other in a first direction; the first and third rows are offset from the second and fourth rows in a second direction that is perpendicular to the first direction; the first and third rows have a first length; the second and fourth rows have a second length; and the first length is longer than the second length in the second direction. The second structure may include an array of apertures forming a hexagonal shape. The system may further include a controller including circuitry configured to perform a continuous scan inspection using the first structure or a leap-and-scan inspection using the second structure.

### BRIEF DESCRIPTION OF THE DRAWINGS

FIG. 1 is a schematic diagram illustrating an exemplary electron beam inspection (EBI) system, consistent with embodiments of the present disclosure.

FIG. 2 is a schematic diagram illustrating an exemplary multi-beam system that is part of the exemplary charged particle beam inspection system of FIG. 1, consistent with embodiments of the present disclosure.

FIG. 3A is a diagrammatic illustration of beamlet generation in a multi-beam system, consistent with embodiments of the present disclosure.

FIG. 3B is a diagrammatic illustration of a MEMS aperture array, consistent with embodiments of the present disclosure, consistent with embodiments of the present disclosure.

FIGS. 4A-4B are diagrammatic illustrations of example aperture arrays for generating beamlets.

FIG. 4C is an example graph of the number of beamlets in different aperture arrays that may be used to scan a wafer in a given FOV at different beamlet pitches.

FIGS. 5A-5C are diagrammatic illustrations of example aperture arrays for generating beamlets.

FIG. 5D is an example graph of the fill factor in different aperture arrays that may be used to scan a wafer in a given FOV at different beamlet pitches.

FIG. 6A is a diagrammatic illustration of example aperture arrays for generating beamlets, consistent with embodiments of the present disclosure.

FIG. 6B is an example graph of the number of beamlets in different aperture arrays that may be used to scan a wafer in a given FOV at different beamlet pitches, consistent with embodiments of the present disclosure.

FIG. 7 is a diagrammatic illustration of an example aperture array for generating beamlets, consistent with embodiments of the present disclosure.

FIG. 8 is an illustration of an example process for inspecting a wafer, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the disclosure. Instead, they are merely examples of apparatuses and methods consistent with aspects related to the subject matter recited in the appended claims. For example, although some embodiments are described in the context of utilizing electron beams, the disclosure is not so limited. Other types of charged particle beams may be similarly applied. Furthermore, other imaging systems may be used, such as optical imaging, photodetection, x-ray detection, or the like.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection may be carried out using a scanning electron microscope (SEM). A SEM can be used to image these extremely small structures, in effect, taking a “picture” of the structures of the wafer. The image can be used to determine if the structure was formed properly and also if it was formed in the proper location. If the structure is defective, then the process can be adjusted so the defect is less likely to recur.

The working principle of a SEM is similar to a camera. A camera takes a picture by receiving and recording brightness and colors of light reflected or emitted from people or objects. A SEM takes a “picture” by receiving and recording energies or quantities of electrons reflected or emitted from the structures. Before taking such a “picture,” an electron beam may be provided onto the structures, and when the electrons are reflected or emitted (“exiting”) from the structures, a detector of the SEM may receive and record the energies or quantities of those electrons to generate an image. To take such a “picture,” some SEMs use a single electron beam (referred to as a “single-beam SEM”), while some SEMs use multiple electron beams (referred to as a “multi-beam SEM”) to take multiple “pictures” of the wafer. By using multiple electron beams, the SEM may provide more electron beams onto the structures for obtaining these multiple “pictures,” resulting in more electrons exiting from the structures. Accordingly, the detector may receive more exiting electrons simultaneously, and generate images of the structures of the wafer with a higher efficiency and a faster speed.

In a multiple charged-particle beam imaging system (e.g., a multi-beam SEM), an aperture array may be used for forming multiple beamlets. The aperture array may include multiple through holes (“apertures”) that may split a single charged-particle beam into multiple beamlets. The number of apertures in an aperture array may affect the throughput of the multiple charged-particle beam imaging system. The throughput indicates how fast the imaging system can complete an inspection task in unit time. During an inspection process, the imaging system may generate images from scanning a surface of a sample. For defect inspection, an image may be generated from each beamlet. As more beamlets are produced by a single charged-particle beam (e.g., the more apertures in an aperture array), more images for scanning a sample can be captured. This can result in a higher throughput of the imaging system.

The geometry of an aperture array may affect the throughput of a multiple charged-particle beam imaging system. However, multiple charged-particle beam imaging systems are typically designed for specific applications that require specific scanning modes. The geometry of an aperture array that optimizes throughput of the imaging system in one scanning mode may not optimize throughput of the imaging system in another scanning mode. To accommodate different applications, a multiple charged-particle beam imaging system may use aperture arrays with different geometries for different scanning modes. The geometry of an aperture array may be selected based on its ability to optimize throughput of the imaging system for a specific scan mode.

Some embodiments of the present disclosure provide, among others things, methods and systems for beam array geometry optimization for a multi-beam inspection system. In some embodiments, the multi-beam system may use an aperture array that has a first set of apertures and a second set of apertures, where the first set of apertures are arranged in a first two-dimensional (2D) shape and the second set of apertures are arranged in a second 2D shape. The multi-beam inspection system may project charged-particle beams onto different sets of apertures. The multi-beam inspection system may control the first and second sets of apertures to operate in different pass-or-block statuses (or “modes”), among others. Apertures in a “pass” status may let through an electron beam. Apertures in a “block” status may block an electron beam. Apertures in other statuses may focus or bend the electron beam, among others. When the multi-beam inspection system projects the charged-particle beams onto the first and second sets of apertures, the first and second sets of apertures may operate in a pass status or a block status such that the charged-particle beams may be projected in the geometry of the first set of apertures or in the geometry of the second set of apertures. Because of the different geometries of the first and second sets of apertures, the multi-beam inspection system may have multiple modes of operations and adapt to multiple applications that optimize throughput of the inspection system.

Relative dimensions of components in drawings may be exaggerated for clarity. Within the following description of drawings, the same or like reference numbers refer to the same or like components or entities, and only the differences with respect to the individual embodiments are described.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

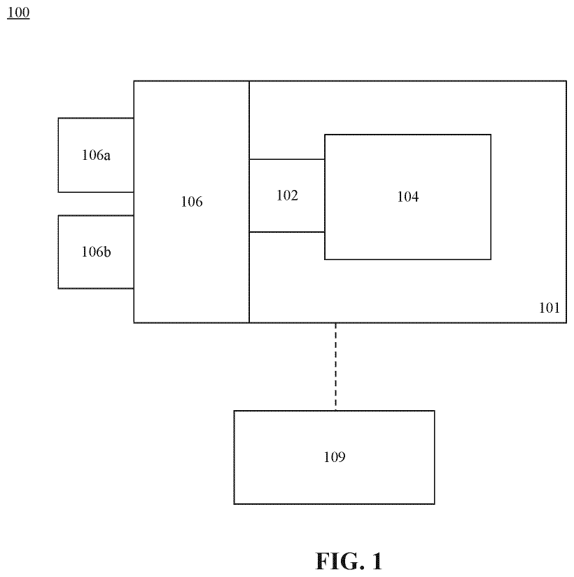

FIG. 1 illustrates an exemplary electron beam inspection (EBI) system 100 consistent with embodiments of the present disclosure. EBI system 100 may be used for imaging. As shown in FIG. 1, EBI system 100 includes a main chamber 101, a load/lock chamber 102, an electron beam tool 104, and an equipment front end module (EFEM) 106. Electron beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by electron beam tool 104. Electron beam tool 104 may be a single-beam system or a multi-beam system.

A controller 109 is electronically connected to electron beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

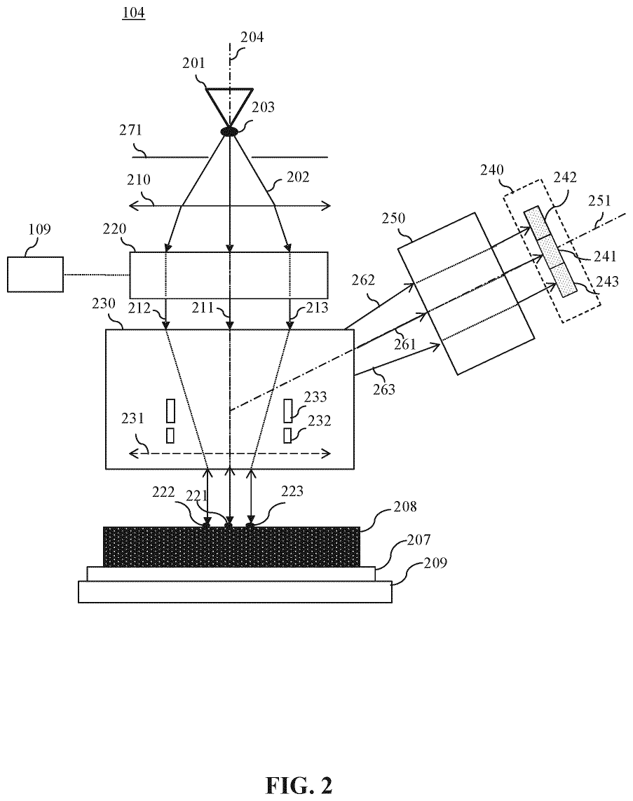

Reference is now made to FIG. 2, which is a schematic diagram illustrating an exemplary electron beam tool 104 including a multi-beam inspection tool that is part of the EBI system 100 of FIG. 1, consistent with embodiments of the present disclosure. Multi-beam electron beam tool 104 (also referred to herein as apparatus 104) comprises an electron source 201, a Coulomb aperture plate (or “gun aperture plate”) 271, a condenser lens 210, a source conversion unit 220, a primary projection system 230, a motorized stage 209, and a sample holder 207 supported by motorized stage 209 to hold a sample 208 (e.g., a wafer or a photomask) to be inspected. Multi-beam electron beam tool 104 may further comprise a secondary projection system 250 and an electron detection device 240. Primary projection system 230 may comprise an objective lens 231. Electron detection device 240 may comprise a plurality of detection elements 241, 242, and 243. A beam separator 233 and a deflection scanning unit 232 may be positioned inside primary projection system 230.

Electron source 201, Coulomb aperture plate 271, condenser lens 210, source conversion unit 220, beam separator 233, deflection scanning unit 232, and primary projection system 230 may be aligned with a primary optical axis 204 of apparatus 104. Secondary projection system 250 and electron detection device 240 may be aligned with a secondary optical axis 251 of apparatus 104.

Electron source 201 may comprise a cathode (not shown) and an extractor or anode (not shown), in which, during operation, electron source 201 is configured to emit primary electrons from the cathode and the primary electrons are extracted or accelerated by the extractor and/or the anode to form a primary electron beam 202 that form a primary beam crossover (virtual or real) 203. Primary electron beam 202 may be visualized as being emitted from primary beam crossover 203.

Source conversion unit 220 may comprise an image-forming element array (not shown), an aberration compensator array (not shown), a beam-limit aperture array (not shown), and a pre-bending micro-deflector array (not shown). In some embodiments, the pre-bending micro-deflector array deflects a plurality of primary beamlets 211, 212, 213 of primary electron beam 202 to normally enter the beam-limit aperture array, the image-forming element array, and an aberration compensator array. In some embodiment, condenser lens 210 is designed to focus primary electron beam 202 to become a parallel beam and be normally incident onto source conversion unit 220. The image-forming element array may comprise a plurality of micro-deflectors or micro-lenses to influence the plurality of primary beamlets 211, 212, 213 of primary electron beam 202 and to form a plurality of parallel images (virtual or real) of primary beam crossover 203, one for each of the primary beamlets 211, 212, and 213. In some embodiments, the aberration compensator array may comprise a field curvature compensator array (not shown) and an astigmatism compensator array (not shown). The field curvature compensator array may comprise a plurality of micro-lenses to compensate field curvature aberrations of the primary beamlets 211, 212, and 213. The astigmatism compensator array may comprise a plurality of micro-stigmators to compensate astigmatism aberrations of the primary beamlets 211, 212, and 213. The beam-limit aperture array may be configured to limit diameters of individual primary beamlets 211, 212, and 213. FIG. 2 shows three primary beamlets 211, 212, and 213 as an example, and it is appreciated that source conversion unit 220 may be configured to form any number of primary beamlets. Controller 109 may be connected to various parts of EBI system 100 of FIG. 1, such as source conversion unit 220, electron detection device 240, primary projection system 230, or motorized stage 209. In some embodiments, as explained in further details below, controller 109 may perform various image and signal processing functions. Controller 109 may also generate various control signals to govern operations of the charged particle beam inspection system.

Condenser lens 210 is configured to focus primary electron beam 202. Condenser lens 210 may further be configured to adjust electric currents of primary beamlets 211, 212, and 213 downstream of source conversion unit 220 by varying the focusing power of condenser lens 210. Alternatively, the electric currents may be changed by altering the radial sizes of beam-limit apertures within the beam-limit aperture array corresponding to the individual primary beamlets. The electric currents may be changed by both altering the radial sizes of beam-limit apertures and the focusing power of condenser lens 210. Condenser lens 210 may be an adjustable condenser lens that may be configured so that the position of its first principle plane is movable. The adjustable condenser lens may be configured to be magnetic, which may result in off-axis beamlets 212 and 213 illuminating source conversion unit 220 with rotation angles. The rotation angles change with the focusing power or the position of the first principal plane of the adjustable condenser lens. Condenser lens 210 may be an anti-rotation condenser lens that may be configured to keep the rotation angles unchanged while the focusing power of condenser lens 210 is changed. In some embodiments, condenser lens 210 may be an adjustable anti-rotation condenser lens, in which the rotation angles do not change when its focusing power and the position of its first principal plane are varied.

Objective lens 231 may be configured to focus beamlets 211, 212, and 213 onto a sample 208 for inspection and may form, in the current embodiments, three probe spots 221, 222, and 223 on the surface of sample 208. Coulomb aperture plate 271, in operation, is configured to block off peripheral electrons of primary electron beam 202 to reduce Coulomb effect. The Coulomb effect may enlarge the size of each of probe spots 221, 222, and 223 of primary beamlets 211, 212, 213, and therefore deteriorate inspection resolution.

Beam separator 233 may, for example, be a Wien filter comprising an electrostatic deflector generating an electrostatic dipole field and a magnetic dipole field (not shown in FIG. 2). In operation, beam separator 233 may be configured to exert an electrostatic force by electrostatic dipole field on individual electrons of primary beamlets 211, 212, and 213. The electrostatic force is equal in magnitude but opposite in direction to the magnetic force exerted by magnetic dipole field of beam separator 233 on the individual electrons. Primary beamlets 211, 212, and 213 may therefore pass at least substantially straight through beam separator 233 with at least substantially zero deflection angles.

Deflection scanning unit 232, in operation, is configured to deflect primary beamlets 211, 212, and 213 to scan probe spots 221, 222, and 223 across individual scanning areas in a section of the surface of sample 208. In response to incidence of primary beamlets 211, 212, and 213 or probe spots 221, 222, and 223 on sample 208, electrons emerge from sample 208 and generate three secondary electron beams 261, 262, and 263. Each of secondary electron beams 261, 262, and 263 typically comprise secondary electrons (having electron energy ≤50 eV) and backscattered electrons (having electron energy between 50 eV and the landing energy of primary beamlets 211, 212, and 213). Beam separator 233 is configured to deflect secondary electron beams 261, 262, and 263 towards secondary projection system 250. Secondary projection system 250 subsequently focuses secondary electron beams 261, 262, and 263 onto detection elements 241, 242, and 243 of electron detection device 240. Detection elements 241, 242, and 243 are arranged to detect corresponding secondary electron beams 261, 262, and 263 and generate corresponding signals which are sent to controller 109 or a signal processing system (not shown), e.g., to construct images of the corresponding scanned areas of sample 208.

In some embodiments, detection elements 241, 242, and 243 detect corresponding secondary electron beams 261, 262, and 263, respectively, and generate corresponding intensity signal outputs (not shown) to an image processing system (e.g., controller 109). In some embodiments, each detection element 241, 242, and 243 may comprise one or more pixels. The intensity signal output of a detection element may be a sum of signals generated by all the pixels within the detection element.

In some embodiments, controller 109 may comprise image processing system that includes an image acquirer (not shown), a storage (not shown). The image acquirer may comprise one or more processors. For example, the image acquirer may comprise a computer, server, mainframe host, terminals, personal computer, any kind of mobile computing devices, and the like, or a combination thereof. The image acquirer may be communicatively coupled to electron detection device 240 of apparatus 104 through a medium such as an electrical conductor, optical fiber cable, portable storage media, IR, Bluetooth, internet, wireless network, wireless radio, among others, or a combination thereof. In some embodiments, the image acquirer may receive a signal from electron detection device 240 and may construct an image. The image acquirer may thus acquire images of sample 208. The image acquirer may also perform various post-processing functions, such as generating contours, superimposing indicators on an acquired image, and the like. The image acquirer may be configured to perform adjustments of brightness and contrast, etc. of acquired images. In some embodiments, the storage may be a storage medium such as a hard disk, flash drive, cloud storage, random access memory (RAM), other types of computer readable memory, and the like. The storage may be coupled with the image acquirer and may be used for saving scanned raw image data as original images, and post-processed images.

In some embodiments, the image acquirer may acquire one or more images of a sample based on an imaging signal received from electron detection device 240. An imaging signal may correspond to a scanning operation for conducting charged particle imaging. An acquired image may be a single image comprising a plurality of imaging areas. The single image may be stored in the storage. The single image may be an original image that may be divided into a plurality of regions. Each of the regions may comprise one imaging area containing a feature of sample 208. The acquired images may comprise multiple images of a single imaging area of sample 208 sampled multiple times over a time sequence. The multiple images may be stored in the storage. In some embodiments, controller 109 may be configured to perform image processing steps with the multiple images of the same location of sample 208.

In some embodiments, controller 109 may include measurement circuitries (e.g., analog-to-digital converters) to obtain a distribution of the detected secondary electrons. The electron distribution data collected during a detection time window, in combination with corresponding scan path data of each of primary beamlets 211, 212, and 213 incident on the wafer surface, can be used to reconstruct images of the wafer structures under inspection. The reconstructed images can be used to reveal various features of the internal or external structures of sample 208, and thereby can be used to reveal any defects that may exist in the wafer.

In some embodiments, controller 109 may control motorized stage 209 to move sample 208 during inspection of sample 208. In some embodiments, controller 109 may enable motorized stage 209 to move sample 208 in a direction continuously at a constant speed. In other embodiments, controller 109 may enable motorized stage 209 to change the speed of the movement of sample 208 overtime depending on the steps of scanning process.

Although FIG. 2 shows that apparatus 104 uses three primary electron beams, it is appreciated that apparatus 104 may use two or more number of primary electron beams. The present disclosure does not limit the number of primary electron beams used in apparatus 104.

Compared with a single charged-particle beam imaging system (“single-beam system”), a multiple charged-particle beam imaging system (“multi-beam system”) may be designed to optimize throughput for different scan modes. Embodiments of this disclosure provide a multi-beam system with the capability of optimizing throughput for different scan modes by using beam arrays with different geometries. adapting to different throughputs and resolution requirements.

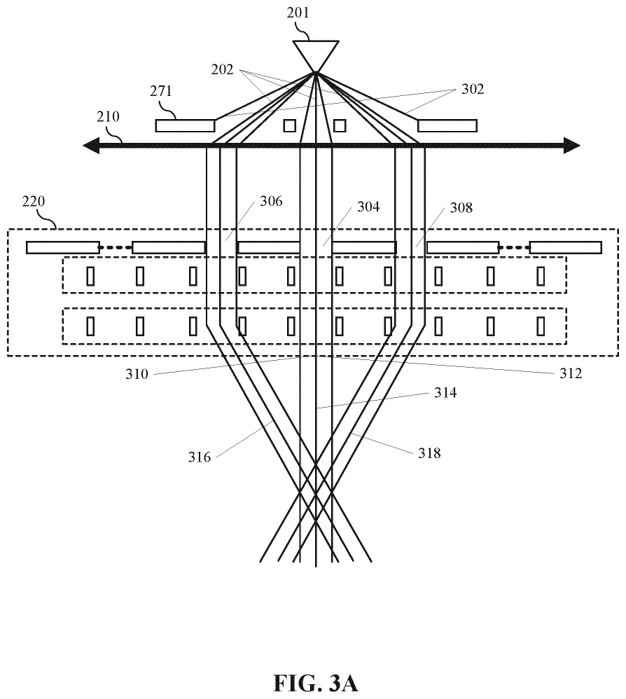

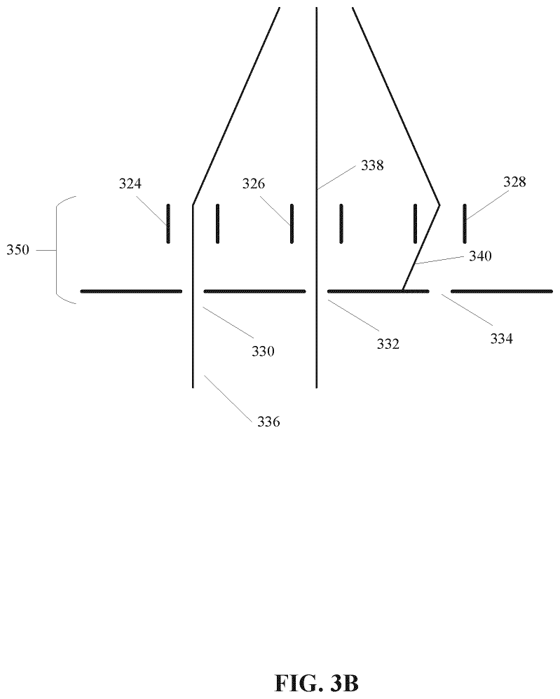

In some embodiments of this disclosure, an apparatus (e.g., implemented as component of source conversion unit 220) may be used for generating arrays of beamlets arranged in different 2D geometries for a multi-beam inspection system. The apparatus may include at least one set of apertures in an aperture array, where each set of apertures includes a different 2D geometric arrangement of apertures. The apparatus may be operated such that a primary charged particle beam (e.g., primary electron beam 202) may irradiate an aperture array based on the scan mode. By adjusting one or more parameters (e.g., a projection area) of the primary charged particle beam, the primary charged particle beam may be incident on an aperture array in accordance with demands of different applications (e.g., scan modes), in which an optimal set of apertures of the aperture array may be selected, and optimal throughput results (e.g., maximum throughput) for each application may be obtained. FIG. 3A illustrates beamlet generation in a multi-beam system that includes such an apparatus. In the example embodiments as shown in FIG. 3A, the multi-beam system may select the set of apertures for generating beamlets and thus may have the capability of adapting to optimize different scan modes, including increasing throughput for different scan modes.

FIG. 3A is a diagrammatic illustration of beamlet generation in a multi-beam system, consistent with embodiments of the present disclosure. For example, a first operation mode may be a scan mode using a first set of apertures while a second operation mode may be a scan mode using a second set of apertures. In FIG. 3A, electron source 201 may emit electrons. Coulomb aperture plate 271 may block off peripheral electrons 302 of primary electron beam 202 to reduce Coulomb effect. Condenser lens 210 may focus primary electron beam 202 to become a parallel beam and be incident onto source conversion unit 220 in a normal direction. Condenser lens 210 may be an adjustable condenser lens as described in parts associated with FIG. 2. In FIG. 3A, a first principal plane of adjustable condenser lens 210 may be adjusted to be close to electron source 201, in which a projection area of primary electron beam 202 may be decreased. That is, the focus power of condenser lens 210 may be enhanced in FIG. 3A.

Source conversion unit 220 may include an aperture array. The aperture array may include apertures 304, 306, and 308. Because condenser lens 210 decreases the projection area of primary electron beam 202, primary electron beam 202 may only be incident onto a portion of the apertures of the aperture array. For example, in FIG. 3A, only apertures 304, 306, and 308 are projected by primary electron beam 202. Apertures of the aperture array or associated components may be controlled to operate in different pass-or-block statuses, to enable or disable electrons from primary electron beam 202 from passing through selected apertures. An aperture or associated component in a pass status may enable a beam to pass through the aperture, and the aperture or associated component in a block status may stop a beam from passing through the aperture. For example, the aperture array may include a first set of apertures having a first combination of apertures in pass or block statuses and a second set of apertures having a second combination of apertures in pass or block statuses.

In some embodiments, the aperture array may be micro-electromechanical systems (MEMS) aperture array, or the associated component may be a MEMS which may be part of a MEMS array, such as a MEMS aperture array. Each aperture of the MEMS aperture array may include a deflection structure (e.g., a magnetic coil, electric plates, or any electromagnetic beam deflecting device) and a chopping aperture downstream from the deflection structure.

FIG. 3B is a diagrammatic illustration of a MEMS aperture array 350, consistent with embodiments of the present disclosure. Aperture array 350 may include multiple deflection structures, including deflection structures 324, 326, and 328, corresponding to chopping apertures 330, 332, and 334, respectively. As shown in FIG. 3B, each chopping aperture may have a hole centrally aligned with the opening of the corresponding deflection structure. The hole of the chopping aperture may be smaller than the opening of the deflection structure. The apertures of aperture array 350 may be independently and individually controlled to be in pass statuses or block statuses. For example, chopping aperture 330 is controlled to be in a pass status, in which deflection structure 324 directs electron beam 336 entering deflection structure 324 to pass straight, and electron beam 336 may exit chopping aperture 330. Similarly, chopping aperture 332 is controlled to be in a pass status, in which deflection structure 326 directs electron beam 338 entering deflection structure 326 to pass straight, and electron beam 338 may exit chopping aperture 332. For another example, chopping aperture 334 is controlled to be in a block status, in which deflection structure 328 directs electron beam 340 to be blanked (e.g., to be deflected away from the entering direction and hit on a wall of chopping aperture 334), and electron beam 340 may be stopped from passing through the hole of chopping aperture 334. A chopping aperture may be controlled to be in a block status depending on the 2D shape of the set of apertures associated with a scan mode. In some embodiments, the deflection structures may be part of a component or components that are separate from the aperture array.

It should be noted that the number of beamlets generated in FIG. 3A is determined by an output angle of the primary electron beam 202 and the pass-or-block statuses of apertures projected by primary electron beam 202. For example, in FIG. 3A, primary electron beam 202 may project and cover apertures 304, 306, and 308. If all of apertures 304, 306, and 308 operate in the pass status, the number of generated beamlets is 3. If only a portion of apertures 304, 306, and 308 operates in the pass status (e.g., only aperture 304 operates in the pass status), the number of generated beamlets is less than 3 (e.g., 1). However, the upper limit of the number of the generated beamlets may be limited by the output angle of primary electron beam 202. For example, as shown in FIG. 3A, if primary electron beam 202 only covers apertures 304, 306, and 308 in its maximum output angle, the upper limit of the number of the generated beamlets may be 3.

As example embodiments FIGS. 3A and 3B show, by controlling the pass-or-block statuses of sets of apertures of different 2D shapes, the multi-beam system may switch in different operation modes adaptive to different demands of throughputs of various applications. Such a design does not significantly increase complexity of the multi-beam system and provide users with more application options in a single solution without incurring significant costs.

As shown in FIG. 3A, source conversion unit 220 may include beam focusing, directing, or deflecting components that may cause beamlets 314, 316, and 318 to converge and cross a common area downstream from source conversion unit 220. It should be noted that FIGS. 3A-3B are mere diagrammatic illustrations for explaining principles and describing example embodiments of this disclosure, and the actual apparatus and system may include more, fewer, or exactly the same components as shown, or having configurations and arrangements of the components in the same or different way.

This disclosure proposes apparatuses and methods for beam array geometry optimization of the multi-beam system. In some embodiments, the apparatus may be implemented as one or more components being part of or associated with source conversion unit 220. For example, source conversion unit 220 may include one or more sets of apertures of an aperture array to be used for different scan modes (e.g., leap-and-scan mode, continuous scan mode) in the multi-beam system. A first set of apertures may enable a first set of beamlets in a first geometric pattern to scan a wafer. A second set of apertures may enable a second set of beamlets in a second geometric pattern to scan the wafer. In some embodiments, the sets of apertures may superimpose each other and be configured to operate in the same pass-or-block status or different pass-or-block statuses. An aperture in a pass status may enable a beam to pass through the aperture, and the aperture in a block status may stop the beam from passing through the aperture. In some embodiments, the pass-or-block statuses of the apertures may be independently controlled by circuitry of source conversion unit 220. In some embodiments, the aperture arrays may be micro-electromechanical systems (MEMS) aperture arrays. In some embodiments, the circuitry may be a processor (e.g., a processor of controller 109 of FIG. 1), a memory storing executable instructions (e.g., a memory of controller 109 of FIG. 1), or a combination thereof. Controlling the pass-or-block statuses of the sets of apertures under different scan modes may ensure only the apertures having the selected beam array geometry may be used for the corresponding scan mode, and no apertures having the non-selected beam array geometry may be used, thereby preventing mistakes in controlling a shape of the beamlets. It should be noted that the multi-beam system may work in any number of any modes.

Correspondingly, when the apparatus includes two or more sets of apertures, and the multi-beam system is capable of working in two or more scan modes, different groups of apertures among the aperture array may be configured to operate in different pass-or-block statuses accordingly. In some embodiments, the pass-or-block statuses of the different groups of apertures may be independently controlled by the circuitry of source conversion unit 220.

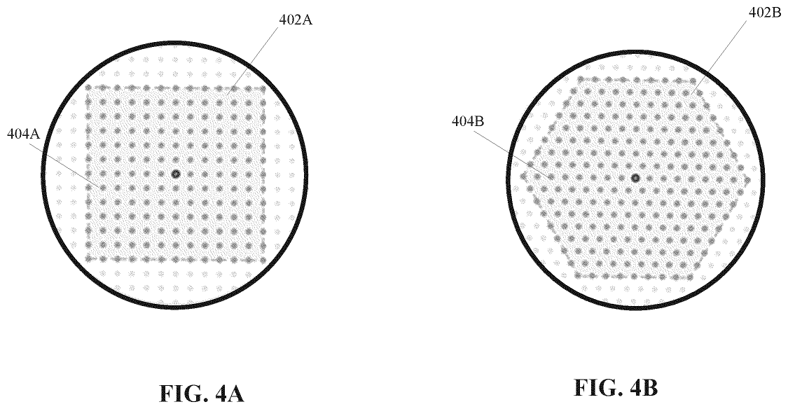

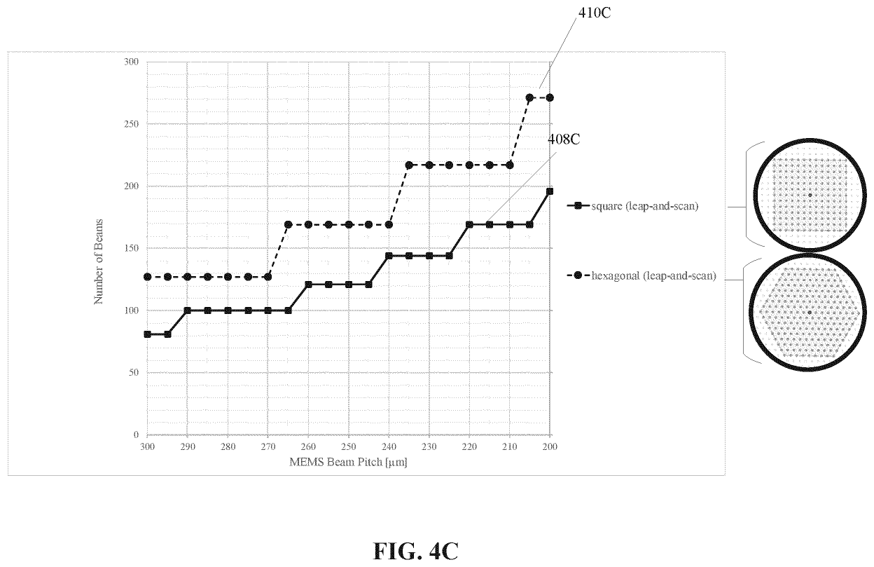

The sizes, locations, and arrangements of the groups of apertures of the aperture array of the apparatus may be in any configuration as long as the primary charged particle beam may be controlled to project onto substantially one group in each operation mode of the multi-beam system. FIGS. 4A-4B, 6A, and 7 are diagrammatic illustrations of example aperture arrays for generating beamlets, consistent with embodiments of the present disclosure. The aperture arrays may be used in source conversion unit 220 in FIG. 2 and FIGS. 3A-3B. In some embodiments, the aperture arrays shown in FIGS. 4A-4B, 6A, and 7 may be MEMS aperture arrays.

Image acquisition using a multi-beam tool may comprise generating a plurality of inspection beams by an electron beam tool (e.g., electron beam tool 104 of FIGS. 1-2) and scanning the beam in a pattern (for example, a raster pattern) over the wafer (e.g., sample 208 of FIG. 2) to be inspected. An image acquirer may be configured to acquire an image of a first imaging area by having the inspection beam scan over the surface of the wafer in a first region and detecting a signal output from a detector (e.g., detection device 240 of FIG. 2). Range of beam scanning may be limited by the field of view (FOV) of the electron beam tool, and thus, the first imaging area may be coincident with the FOV. To image another area, the wafer is moved by a sample stage (e.g., motorized stage 209 of FIG. 2) and the beam is scanned over a new area of the wafer. In a leap-and-scan mode, imaging may be conducted at a particular region within the FOV, and when complete, the stage is moved and the process repeats.

In a continuous-scan mode, imaging may be conducted continuously while a wafer is carried by a movable stage along x- and y-directions. For example, the stage may be moved in a continuous linear motion under a charged particle beam column Meanwhile, one or more charged particle beams (e.g., primary beamlets 211, 212, or 213 of FIG. 2) generated by a charged particle source (e.g., electron source 201 of FIG. 2) may be scanned linearly back-and-forth along scan lines in a pattern, such as a raster pattern. Thus, the one or more charged particle beams are moved so as to cover the moving wafer in discrete strip-shaped segments. More information on continuous scanning using a multi-beam apparatus can be found in U.S. Patent Application No. 62/850,461, which is incorporated by reference in its entirety.

FIG. 4A shows an example aperture array 402A having a set of apertures 404A in a square pattern (hereinafter referred to as square aperture array) that may be used in source conversion unit 220. The dots depicted in the shaded and unshaded sections represent the total number of possible beamlets that may scan a particular region of a wafer within the FOV at a given pitch (center-to-center distance of the beamlets or apertures). A fill factor of the beamlets for an aperture array may be determined by calculating the fraction of beamlets that may be used to scan under an aperture array out of the total number of possible beamlets for a region of a wafer within the FOV. For example, the fill factor may be the fraction of dots in the shaded square region out of the total number of dots in the FOV. In a multi-beam system (e.g., EBI system 100 of FIG. 1) operating in a leap-and-scan mode, the beamlet fill factor using square aperture array 402A may be 64%.

FIG. 4B shows an example aperture array 402B having a set of apertures 404B in a hexagonal pattern (hereinafter referred to as hexagonal aperture array) that may be used in source conversion unit 220 Similar to FIG. 4A, the dots depicted in the shaded and unshaded sections represent the total number of possible beamlets that may scan a particular region of a wafer within the FOV at a given pitch. The fill factor may be the fraction of dots in the shaded hexagonal region out of the total number of dots in the FOV. In a multi-beam system (e.g., EBI system 100 of FIG. 1) operating in a leap-and-scan mode, the beamlet fill factor using hexagonal aperture array 402B may be 83%.

FIG. 4C shows an example graph of the number of beamlets in different aperture arrays that may be used to scan a wafer in a given FOV at different beamlet pitches. The horizontal axis may show the beamlet pitch in micrometers (“μm”), decreasing in value from left to right. The vertical axis may show the number of beamlets that may be used to scan a wafer in a given FOV. Curve 408C represents the number of beamlets that may be used in a square aperture array (e.g., square aperture array 402A of FIG. 4A) with varying beamlet pitches to scan a wafer in a leap-and-scan mode. Curve 410C represents the number of beamlets that may be used in a hexagonal aperture array (e.g., hexagonal aperture array 402B of FIG. 4B) with varying beamlet pitches to scan a wafer in a leap-and-scan mode. As shown in FIG. 4C, the number of beamlets that may be used in either aperture array increases as the beamlet pitch decreases since the number of beamlets that may be used in an aperture array increases as the distance between each aperture decreases.

In some embodiments, the multi-beam system may scan a portion of a wafer using hexagonal aperture array 402B and leap to scan another adjoining portion of the wafer (e.g., by using a honeycomb pattern for scanning the wafer). For example, a square aperture array with beamlet pitches of 210 μm may allow 169 beamlets to scan the wafer in a FOV using a leap-and-scan mode while a hexagonal aperture array with beamlet pitches of 210 μm may allow 217 beamlets to scan the wafer in the same FOV using the same leap-and-scan mode. Therefore, hexagonal aperture array 402B may be more desirable over square aperture array 402A in a multi-beam system using leap-and-scan mode since aperture array 402B results in higher imaging throughput.

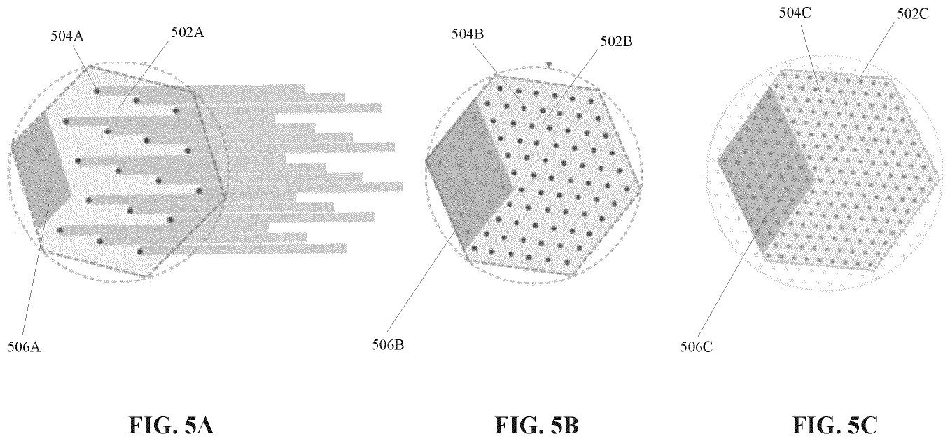

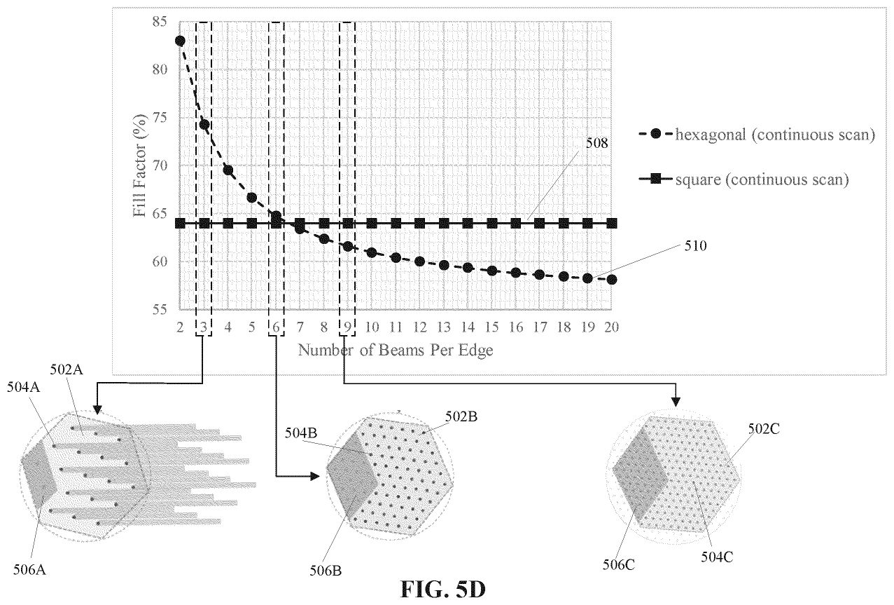

FIGS. 5A, 5B, and 5C show exemplary rotated hexagonal aperture arrays 502A, 502B, and 502C, respectively, that may be used in source conversion unit 220. FIG. 5D shows an example graph of the fill factor in different aperture arrays that may be used to scan a wafer in a given FOV at different beamlet pitches. Hexagonal aperture arrays 502A, 502B, and 502C include sets of apertures 504A, 504B, and 504C, respectively, with decreasing beamlet pitches in that order. For example, hexagonal aperture array 502A may have three beamlets along each edge of the aperture array, hexagonal aperture array 502B may have six beamlets along each edge of the aperture array, and hexagonal aperture array 502C may have nine beamlets along each edge of the aperture array. Although a hexagonal aperture array increases throughput of an imaging system compared to a square aperture array when used in a leap-and-scan mode, a hexagonal aperture array may not be preferred for use in a continuous scan mode. Due to the shape of hexagonal aperture arrays 502A, 502B, and 502C, use of the hexagonal aperture arrays in a multi-beam system operating in continuous scan mode results in regions 506A, 506B, and 506C of beams that are not utilized during the scanning of the wafer as the scanning using beams in regions 506A, 506B, and 506C would overlap with previous scans performed by utilized beams. That is, regions 506A, 506B, and 506C are “unutilized” regions in the FOV. Furthermore, as the beamlet pitches decrease from hexagonal aperture array 502A to hexagonal aperture array 502C, the fill factor decreases (e.g., 74% to 65% to 61%), as represented by curve 510 in FIG. 5D, in continuous scan mode due to the unutilized regions. Curve 508 represents the fill factor of a square aperture array at different beamlet pitches in continuous scan mode. As shown in FIG. 5D, as the number of beams per edge increases, a square aperture array may be more desirable than a hexagonal aperture array to increase imaging throughput (e.g., increase the number of beamlets used to scan a wafer) when operating an imaging system in continuous scan mode. However, a square aperture array may not maximize imaging throughput in continuous scan mode.

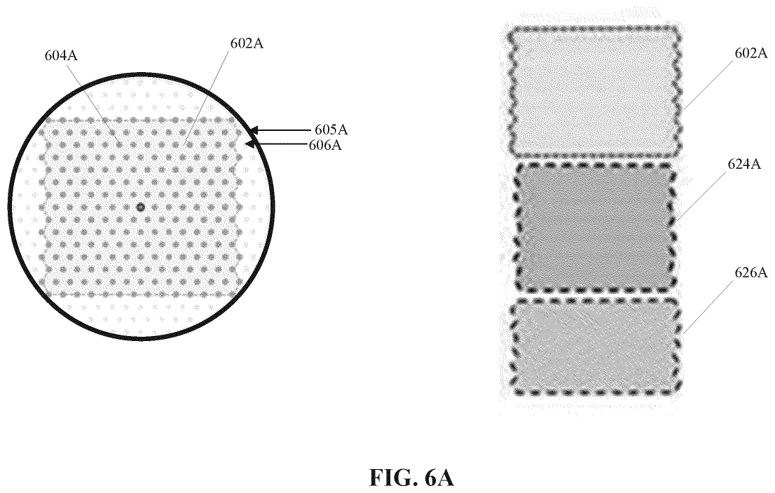

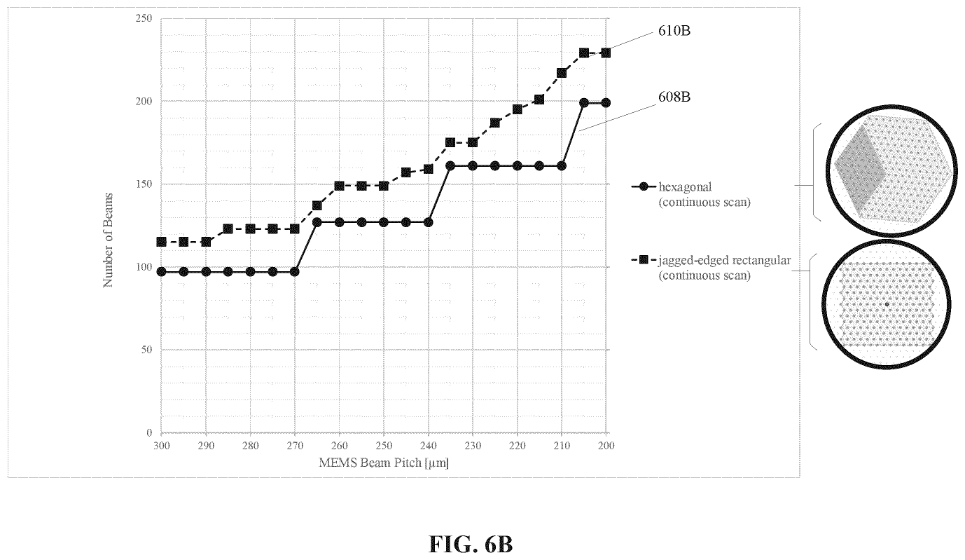

FIG. 6A shows an example aperture array 602A having a set of apertures 604A in a jagged-edged rectangular pattern (hereinafter referred to as jagged-edged rectangular aperture array) that may be used in source conversion unit 220. For example, jagged-edged rectangular aperture array 602A may include a first row of apertures 605A and a second row of apertures 606A that is below first row 605A. In some embodiments, first row 605A may be longer (e.g., have more apertures) than second row 606A, while in some other embodiments, first row 605A and 606A may have the same length but may be offset from each other. As shown in FIG. 6A, first row 605A and second row 606A may be offset from each other in a horizontal direction, giving aperture array 602A its jagged-edged rectangular shape. Jagged-edged rectangular aperture array 602A may include a plurality of first rows 605A and a plurality of second rows 606A, where first rows 605A and second rows 606A alternate in a direction (e.g., vertically) perpendicular to the direction (e.g., horizontally) in which rows 605A and 606A extend.

One of the advantages of using the jagged-edged rectangular aperture array 602 is that when used in a continuous-scan mode, the unutilized regions are minimized. For example, in the embodiments shown in FIG. 6A, when jagged-edged rectangular aperture array 602 is rotated in a particular manner, there may be no unutilized regions. Accordingly, in used in continuous scan mode, the fill factor of jagged-edged rectangular aperture array 602A in a multi-beam system may be higher than the fill factor of hexagonal aperture array 502C due to the unutilized regions of array 502C is. That is, using jagged-edged rectangular aperture array 602A may result in higher throughput of the imaging system when operating in continuous scan mode (e.g., fill factor of 81%).

In some embodiments, the shape of the jagged-edged rectangular aperture array 624A may be modified by adding or reducing rows. For example, a jagged-edged rectangular aperture array 624A may have more alternating rows than jagged-edged rectangular aperture array 602A, where each alternating row is shorter (e.g., has less apertures) than rows 605A and 606A. In some embodiments, a jagged-edged rectangular aperture array 626A may have less alternating rows than jagged-edged rectangular aperture array 602A, where each alternating row is longer (e.g., has more apertures) than rows 605A and 606A.

FIG. 6B shows an example graph of the number of beamlets in different aperture arrays that may be used to scan a wafer in a given FOV at different beamlet pitches. The horizontal axis may show the beamlet pitch in micrometers, decreasing in value from left to right. The vertical axis may show the number of beamlets that may be used to scan a wafer in a given FOV. Curve 608B represents the number of beamlets that may be used in a hexagonal aperture array (e.g., hexagonal aperture array 502C of FIG. 5C) with varying beamlet pitches to scan a wafer in a continuous scan mode. Curve 610B represents the number of beamlets that may be used in a jagged-edged rectangular aperture array (e.g., jagged-edged rectangular array 602A of FIG. 6A) with varying beamlet pitches to scan a wafer in a continuous scan mode. As shown in FIG. 6B, the number of beamlets that may be used in either aperture array increases as the beamlet pitch decreases since the number of beamlets that may be used in an aperture array increases as the distance between each aperture decreases. Because a jagged-edged rectangular aperture array may not result in unutilized regions when operating an imaging system in continuous scan mode, a jagged-edged rectangular aperture array may achieve higher throughput and may be preferable over a hexagonal aperture array. For example, in a continuous scan mode, a hexagonal aperture array with beamlet pitches of 210 μm may allow 161 beamlets to scan a wafer in a FOV while a jagged-edged rectangular aperture array with beamlet pitches of 210 μm may allow 217 beamlets to scan the wafer in the same FOV.

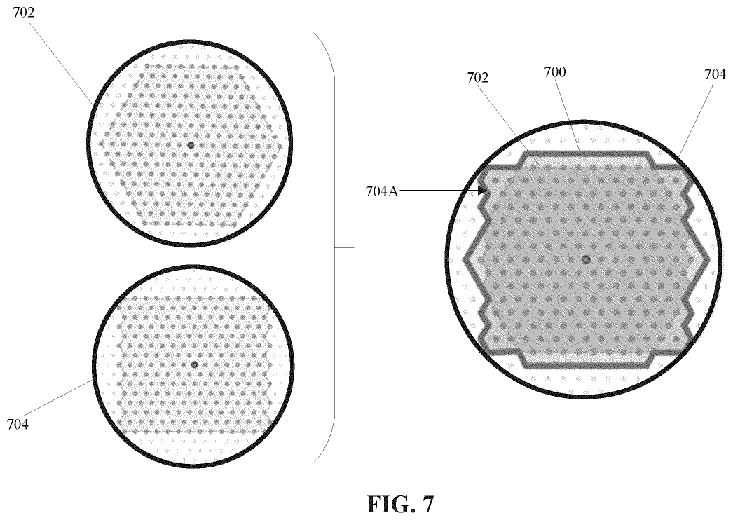

FIG. 7 shows an example of aperture array 700 including a first set of apertures forming a 2D hexagonal shape 702 (e.g., hexagonal aperture array 402B of FIG. 4B) and a second set of apertures forming a 2D jagged-edged rectangular shape 704 (e.g., jagged-edged rectangular aperture array 602A of FIG. 6A). Aperture array 700 may have a hexagonal shape with four sets of jagged corner apertures 704A. Each set of jagged corner apertures 704A may include at least two rows of apertures that are offset in a direction (e.g., vertically) perpendicular to the direction (e.g., horizontally) in which the rows extend. Each offset row may extend from an edge of the hexagonal shape that extends greater than 90 degrees from a horizontal edge of the hexagonal shape.

In some embodiments, a multi-beam system (e.g., EBI system 100 of FIG. 1) may operate in different scan modes. For example, a multi-beam system may operate in leap-and-scan mode for high resolution applications and in continuous scan mode for high current applications. In some embodiments, hexagonal set of apertures 702 (e.g., apertures 330 or 332 of FIG. 3B) may be controlled to operate in pass statuses to enable electrons from a primary electron beam (e.g., primary electron beam 202 of FIG. 2) to pass through hexagonal set of apertures 702 during a leap-and-scan mode. During a leap-and-scan mode, apertures of jagged-edged rectangular set of apertures 704 (e.g., aperture 334 of FIG. 3B) that are not shared with hexagonal set of apertures 702 (e.g., jagged corner apertures 704A) may be controlled to operate in block statuses to block electrons from the primary electron beam from passing through the non-shared apertures. For example, each aperture may be independently and individually controlled to be in either a pass status, in which a deflection structure (e.g., deflection structures 324 or 326 of FIG. 3B) may direct an electron beam (e.g., electron beams 336 or 338 of FIG. 3B) to pass straight into the aperture, or a block status, in which a deflection structure (e.g., deflection structure 328 of FIG. 3B) may direct an electron beam (e.g., electron beam 340 of FIG. 3B) to be blanked (e.g., deflected away from the entering direction and hit on a wall of the aperture) and the electron beam may be stopped from passing through the aperture.

In some embodiments, jagged-edged rectangular set of apertures 704 may be controlled to operate in pass statuses to enable electrons from a primary electron beam to pass through jagged-edged rectangular set of apertures 704 during a continuous scan mode. During a continuous scan mode, apertures of hexagonal set of apertures 702 that are not shared with jagged-edged rectangular set of apertures 704 may be controlled to operate in block statuses to block electrons from the primary electron beam from passing through the non-shared apertures. In some embodiments, the darker region in the center of aperture array 700 shows apertures that may be controlled to always operate in pass statuses to enable electrons from a primary electron beam to pass through the apertures during both a leap-and-scan mode and a continuous scan mode.

While FIG. 7 does not explicitly show apertures along the boundary of aperture array 700, it is appreciated that apertures exist on the boundary to give aperture array 700 its unique shape.

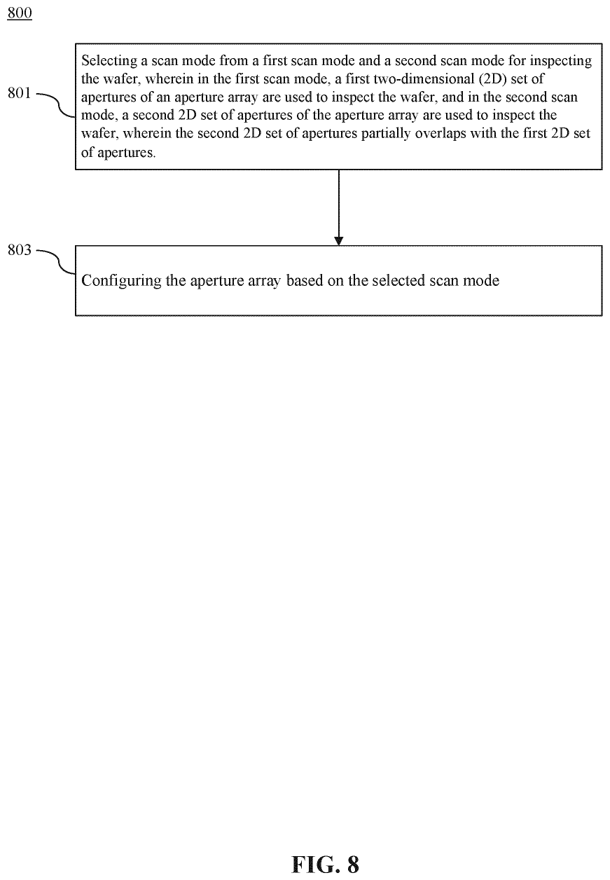

FIG. 8 shows an example process 800 of inspecting wafer. The process may include an inspection system (e.g., EBI system 100 of FIG. 1) that may scan a wafer (e.g., sample 208 of FIG. 2) using an aperture array (e.g., hexagonal aperture array 402B of FIG. 4B; aperture array 602A of FIG. 6A; aperture array 700 of FIG. 7). The aperture array may include a first set of apertures forming a 2D hexagonal shape (e.g., set of apertures 702 of FIG. 7; hexagonal aperture array 402B of FIG. 4B) and a second set of apertures forming a 2D jagged-edged rectangular shape (e.g., apertures 704 of FIG. 7; jagged-edged rectangular aperture array 602A of FIG. 6A). The aperture array may have a hexagonal shape with four sets of jagged corner apertures (e.g., jagged corner apertures 704A of FIG. 7). Each set of the jagged corner apertures may include at least two rows of apertures that are offset in a direction (e.g., vertically) perpendicular to the direction (e.g., horizontally) in which the rows extend. Each offset row may extend from an edge of the hexagonal shape that extends greater than 90 degrees from a horizontal edge of the hexagonal shape.

In step 801, the inspection system may select a scan mode from a first scan mode and a second scan mode for inspecting the wafer. In the first scan mode, the first 2D set of apertures of the aperture array may be used to inspect the wafer. For example, the inspection system may use the first 2D set of apertures to operate in leap-and-scan mode for high resolution applications and in continuous scan mode for high current applications. In some embodiments, the hexagonal set of apertures (e.g., apertures 330 or 332 of FIG. 3B) may be controlled to operate in pass statuses to enable electrons from a primary electron beam (e.g., primary electron beam 202 of FIG. 2) to pass through the hexagonal set of apertures during a leap-and-scan mode. During a leap-and-scan mode, apertures of the jagged-edged rectangular set of apertures (e.g., aperture 334 of FIG. 3B) that are not shared with the hexagonal set of apertures (e.g., jagged corner apertures 704A) may be controlled to operate in block statuses to block electrons from the primary electron beam from passing through the non-shared apertures. For example, each aperture may be independently and individually controlled to be in either a pass status, in which a deflection structure (e.g., deflection structures 324 or 326 of FIG. 3B) may direct an electron beam (e.g., electron beams 336 or 338 of FIG. 3B) to pass straight into the aperture, or a block status, in which a deflection structure (e.g., deflection structure 328 of FIG. 3B) may direct an electron beam (e.g., electron beam 340 of FIG. 3B) to be blanked (e.g., deflected away from the entering direction and hit on a wall of the aperture) and the electron beam may be stopped from passing through the aperture.

In the second scan mode, the second 2D set of apertures of the aperture array may be used to inspect the wafer. For example, the jagged-edged rectangular set of apertures may be controlled to operate in pass statuses to enable electrons from a primary electron beam to pass through the jagged-edged rectangular set of apertures during a continuous scan mode. During a continuous scan mode, apertures of the hexagonal set of apertures that are not shared with the jagged-edged rectangular set of apertures may be controlled to operate in block statuses to block electrons from the primary electron beam from passing through the non-shared apertures. In some embodiments, the second 2D set of apertures may partially overlap with the first 2D set of apertures (e.g., darker region in the center of aperture array 700 of FIG. 7). The overlapping apertures may be controlled to always operate in pass statuses to enable electrons from a primary electron beam to pass through the apertures during both a leap-and-scan mode and a continuous scan mode.

In step 803, the inspection system may configure the aperture array based on the selected scan mode. For example, if the continuous scan mode is selected, the aperture array may be rotated appropriately to maximize the scanning area corresponding to the jagged-edged rectangular set of apertures. On the other hand, if the leap-and-scan mode is selected, the aperture array may not need to be rotated. Moreover, the pass and block statuses of the apertures of the aperture array can be adjusted accordingly.

Aspects of the present disclosure are set out in the following numbered clauses:

1. A microelectromechanical system (MEMS) structure comprising:

a first two-dimensional (2D) set of apertures configured to be used in a first scan mode; and

a second 2D set of apertures configured to be used in a second scan mode different from the first scan mode;
wherein the second 2D set of apertures partially overlaps with the first 2D set of apertures.
   2. The structure of clause 1, wherein the first 2D set of apertures comprises an array of apertures forming a jagged-edged rectangular shape.
   3. The structure of clause 1, wherein the first 2D set of apertures includes apertures not used in the second scan mode and the second 2D set of apertures includes apertures not used in the first scan mode.
   4. The structure of any one of clauses 1-3, wherein the first 2D set of apertures comprises:

a first row of apertures;

a second row of apertures;

a third row of apertures;

a fourth row of apertures;

wherein:
the first, second, third, and fourth rows are parallel to each other in a first direction;
the first and third rows are offset from the second and fourth rows in a second direction that is perpendicular to the first direction.
   5. The structure of clause 3, wherein the offset comprises apertures that do not overlap in the second direction.
   6. The structure of any one of clauses 4-5, wherein the first and third rows have a first length and the second and fourth rows have a second length, and the first length is longer than the second length in the second direction.
   7. The structure of clause 6, wherein the first row, the second row, the third row, and the fourth row alternate in the first direction.
   8. The structure of any one of clauses 1-7, wherein the second 2D set of apertures comprises an array of apertures forming a hexagonal shape.
   9. The structure of any one of clauses 1-8, wherein the first scan mode is a continuous scan mode.
   10. The structure of clause 9, wherein the first 2D set of apertures are configured to be rotated when operating in the continuous scan mode.
   11. The structure of any one of clauses 1-10 wherein the second scan mode is a leap-and-scan mode.
   12. A microelectromechanical system (MEMS) structure comprising:

a first two-dimensional (2D) set of apertures comprising an array of apertures forming a jagged-edged rectangular shape; and

a second 2D set of apertures comprising an array of apertures forming a hexagonal shape;

wherein the second 2D set of apertures partially overlaps with the first 2D set of apertures; and

wherein the first 2D set of apertures is configured to be used in a first scan mode and the second 2D set of apertures is configured to be used in a second scan mode different from the first scan mode.

13. The structure of clause 12, wherein the first 2D set of apertures includes apertures not used in the second scan mode and the second 2D set of apertures includes apertures not used in the first scan mode.
14. The structure of any one of clauses 12-13, wherein the first 2D set of apertures comprises:

a first row of apertures;

a second row of apertures;

a third row of apertures;

a fourth row of apertures;

wherein:
the first, second, third, and fourth rows are parallel to each other in a first direction;
the first and third rows are offset from the second and fourth rows in a second direction that is perpendicular to the first direction.
   15. The structure of clause 14, wherein the offset comprises apertures that do not overlap in the second direction.
   16. The structure of any one of clauses 14-15, wherein the first and third rows have a first length and the second and fourth rows have a second length, and the first length is longer than the second length in the second direction.
   17. The structure of clause 16, wherein the first row, the second row, the third row, and the fourth row alternate in the first direction.
   18. The structure of any one of clauses 12-17, wherein the first scan mode is a continuous scan mode.
   19. The structure of clause 18, wherein the first 2D set of apertures are configured to be rotated when operating in the continuous scan mode.
   20. The structure of any one of clauses 12-19 wherein the second scan mode is a leap-and-scan mode.
   21. A microelectromechanical system (MEMS) structure comprising:

an array of apertures forming a hexagonal shape with four sets of jagged corner apertures;

wherein each set of jagged corner apertures comprises:
two rows of apertures that extend in a first direction, wherein the two rows of apertures are offset in a second direction perpendicular to the first direction, wherein
each row extends in the first direction from a first edge of the hexagonal shape, and wherein the first edge of the hexagonal shape extends in a third direction greater than 90 degrees from a second edge of the hexagonal shape that extends in the first direction.
   22. The structure of clause 21, wherein the array comprises a first 2D set of apertures forming a jagged-edged rectangular shape.
   23. The structure of clause 22, wherein the jagged-edged rectangular shape comprises at least some of the apertures forming the hexagonal shape and the four sets of jagged corner apertures.
   24. The structure of any one of clauses 21-23 wherein the array comprises a second 2D set of apertures forming the hexagonal shape.
   25. The structure of any one of clauses 22-24, wherein the first 2D set of apertures includes apertures not used in a second scan mode and the second 2D set of apertures includes apertures not used in a first scan mode.
   26. The structure of any one of clauses 21-25, wherein the offset comprises apertures that do not overlap in the second direction.
   27. The structure of any one of clauses 25-26, wherein the first scan mode is a continuous scan mode.
   28. The structure of any one of clauses 25-27, wherein the first 2D set of apertures are configured to be rotated when operating in the continuous scan mode.
   29. The structure of any one of clauses 25-28 wherein the second scan mode is a leap-and-scan mode.
   30. A microelectromechanical system (MEMS) structure comprising:

a first row of apertures;

a second row of apertures positioned below the first row of apertures;

a third row of apertures positioned below the second row of apertures; and

a fourth row of apertures positioned below the third row of apertures;

wherein:
the first, second, third, and fourth rows are parallel to each other in a first direction; and
the first and third rows are offset from the second and fourth rows in a second direction that is perpendicular to the first direction;
   31. The structure of clause 30, wherein the first and third rows have a first length and the second and fourth rows have a second length, and the first length is longer than the second length in the second direction.
   32. The structure of clause 31, wherein the first row, the second row, the third row, and the fourth row alternate in the first direction.
   33. The structure of any one of clauses 30-32, wherein the structure is configured to be used in a continuous scan mode of a multi-beam inspection system.
   34. The structure of clause 33, wherein the structure is configured to be rotated when operating in the continuous scan mode.
   35. A microelectromechanical system (MEMS) structure comprising:

a first structure, comprising:
a first row of apertures;
a second row of apertures;
a third row of apertures;
a fourth row of apertures;
wherein:
   the first, second, third, and fourth rows are parallel to each other in a first direction; and
   the first and third rows are offset from the second and fourth rows in a second direction that is perpendicular to the first direction;

a second structure comprising an array of apertures forming a hexagonal shape; and

wherein the first structure is superimposed on the second structure.

36. The MEMS structure of clause 35, wherein the first and third rows have a first length and the second and fourth rows have a second length, and the first length is longer than the second length in the second direction.
37. The MEMS structure of clause 36, wherein the first row, the second row, the third row, and the fourth row alternate in the first direction.
38. The MEMS structure of any one of clauses 35-37, wherein the first structure is configured to be used in a continuous scan mode of a multi-beam inspection system.
39. The MEMS structure of clause 38, wherein the first structure is configured to be rotated when operating in the continuous scan mode.
40. The MEMS structure of any one of clauses 35-39, wherein the second structure is configured to be used in a leap-and-scan mode of a multi-beam inspection system.
41. A charged particle multi-beam system for generating a plurality of beams for inspecting a wafer positioned on a stage, the system comprising:

a first structure, comprising:
a first row of apertures;
a second row of apertures;
a third row of apertures;
a fourth row of apertures;
wherein:
   the first, second, third, and fourth rows are parallel to each other in a first direction; and
   the first and third rows are offset from the second and fourth rows in a second direction that is perpendicular to the first direction;

a second structure comprising an array of apertures forming a hexagonal shape; and

a controller including circuitry configured to perform a continuous scan inspection using the first structure or a leap-and-scan inspection using the second structure.

42. The system of clause 41, wherein the first and third rows have a first length and the second and fourth rows have a second length, and the first length is longer than the second length in the second direction.
43. The system of clause 42, wherein the first row, the second row, the third row, and the fourth row alternate in the first direction.
44. The system of any one of clauses 41-43, wherein the circuitry is further configured to rotate the first structure when performing the continuous scan inspection.
45. A method for inspecting a wafer positioned on a stage, the method comprising:

selecting a scan mode from a first scan mode and a second scan mode for inspecting the wafer, wherein:
in the first scan mode, a first two-dimensional (2D) set of apertures of an aperture array are used to inspect the wafer, and
in the second scan mode, a second 2D set of apertures of the aperture array are used to inspect the wafer, wherein the second 2D set of apertures partially overlaps with the first 2D set of apertures; and configuring the aperture array based on the selected scan mode.
   46. The method of clause 45, wherein the first 2D set of apertures comprises an array of apertures forming a jagged-edged rectangular shape.
   47. The method of clause 45, wherein the first 2D set of apertures includes apertures not used in the second scan mode and the second 2D set of apertures includes apertures not used in the first scan mode.
   48. The method of any one of clauses 45-47, wherein the first 2D set of apertures comprises:

a first row of apertures;

a second row of apertures;

a third row of apertures;

a fourth row of apertures;

wherein:
the first, second, third, and fourth rows are parallel to each other in a first direction;
the first and third rows are offset from the second and fourth rows in a second direction that is perpendicular to the first direction.
   49. The method of clause 47, wherein the offset comprises apertures that do not overlap in the second direction.
   50. The method of any one of clauses 48-49, wherein the first and third rows have a first length and the second and fourth rows have a second length, and the first length is longer than the second length in the second direction.
   51. The method of clause 50, wherein the first row, the second row, the third row, and the fourth row alternate in the first direction.
   52. The method of any one of clauses 45-51, wherein the second 2D set of apertures comprises an array of apertures forming a hexagonal shape.
   53. The method of any one of clauses 45-52, wherein the first scan mode is a continuous scan mode.
   54. The method of clause 53, wherein the first 2D set of apertures are configured to be rotated when operating in the continuous scan mode.
   55. The method of any one of clauses 45-54 wherein the second scan mode is a leap-and-scan mode.

It should be noted that more example embodiments of aperture arrays are possible, which are not limited by examples of presented in this disclosure.

A non-transitory computer readable medium may be provided that stores instructions for a processor (e.g., processor of controller 109 of FIGS. 1-2) to carry out selecting the mode, configuring the aperture array based on the selected mode, image processing, data processing, beamlet scanning, database management, graphical display, operations of a charged particle beam apparatus, or another imaging device, or the like. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM or any other flash memory, NVRAM, a cache, a register, any other memory chip or cartridge, and networked versions of the same.

It will be appreciated that the embodiments of the present disclosure are not limited to the exact construction that has been described above and illustrated in the accompanying drawings, and that various modifications and changes may be made without departing from the scope thereof.

1. A microelectromechanical system (MEMS) structure comprising:
a first two-dimensional (2D) set of apertures configured to be used in a first scan mode; and
a second 2D set of apertures configured to be used in a second scan mode different from the first scan mode;
wherein the second 2D set of apertures partially overlaps with the first 2D set of apertures.

2. The structure of claim 1, wherein the first 2D set of apertures comprises an array of apertures forming a jagged-edged rectangular shape.

3. The structure of claim 1, wherein the first 2D set of apertures includes apertures not used in the second scan mode and the second 2D set of apertures includes apertures not used in the first scan mode.

4. The structure of claim 1, wherein the first 2D set of apertures comprises:
a first row of apertures;
a second row of apertures;
a third row of apertures;
a fourth row of apertures;
wherein:
the first, second, third, and fourth rows are parallel to each other in a first direction;
the first and third rows are offset from the second and fourth rows in a second direction that is perpendicular to the first direction.

5. The structure of claim 3, wherein the offset comprises apertures that do not overlap in the second direction.

6. The structure of claim 4, wherein the first and third rows have a first length and the second and fourth rows have a second length, and the first length is longer than the second length in the second direction.

7. The structure of claim 6, wherein the first row, the second row, the third row, and the fourth row alternate in the first direction.

8. The structure of claim 1, wherein the second 2D set of apertures comprises an array of apertures forming a hexagonal shape.

9. The structure of claim 1, wherein the first scan mode is a continuous scan mode.

10. The structure of claim 9, wherein the first 2D set of apertures are configured to be rotated when operating in the continuous scan mode.

11. The structure of claim 1 wherein the second scan mode is a leap-and-scan mode.

12. A method for inspecting a wafer positioned on a stage, the method comprising:
selecting a scan mode from a first scan mode and a second scan mode for inspecting the wafer, wherein:
in the first scan mode, a first two-dimensional (2D) set of apertures of an aperture array are used to inspect the wafer, and
in the second scan mode, a second 2D set of apertures of the aperture array are used to inspect the wafer, wherein the second 2D set of apertures partially overlaps with the first 2D set of apertures; and
configuring the aperture array based on the selected scan mode.

13. The method of claim 12, wherein the first 2D set of apertures comprises an array of apertures forming a jagged-edged rectangular shape.

14. The method of claim 12, wherein the first 2D set of apertures includes apertures not used in the second scan mode and the second 2D set of apertures includes apertures not used in the first scan mode.

15. The method of claim 12, wherein the first 2D set of apertures comprises:
a first row of apertures;
a second row of apertures;
a third row of apertures;
a fourth row of apertures;
wherein:
the first, second, third, and fourth rows are parallel to each other in a first direction;
the first and third rows are offset from the second and fourth rows in a second direction that is perpendicular to the first direction.

16. The method of claim 15, wherein the offset comprises apertures that do not overlap in the second direction.

17. The method of claim 15, wherein the first and third rows have a first length and the second and fourth rows have a second length, and the first length is longer than the second length in the second direction.

18. The method of claim 15, wherein the first row, the second row, the third row, and the fourth row alternate in the first direction.

19. The method of claim 12, wherein the second 2D set of apertures comprises an array of apertures forming a hexagonal shape.

20. The method of claim 12, wherein the first scan mode is a continuous scan mode.
